(19) United States
(12) Patent Application Publication
(10) Pub. No.: US 2004/0084151 A1
(43) Pub. Date: May 6, 2004

(54) Magnetron plasma etching apparatus

(75) Inventor: Dong-Soo Kim, Pyeongtaek-si (KR)

Correspondence Address: R. Neil Sudol, 714 Colorado Avenue, Bridgeport, CT, 06605-1601, US

(73) Assignee: ANS INC., Pyeongtaek-si (KR)

(21) Appl. No.: 10/627,338

(22) Filed: Jul. 23, 2003

(30) Foreign Application Priority Data
Jul. 31, 2002 (KR) 10-2002-0045185

(51) Int. Cl. H01L 21/306

(52) U.S. Cl. 156/345.46

(57) ABSTRACT

The present invention relates to plasma etching apparatus adapted to a semiconductor fabrication process, etc. which includes a process chamber which may be set to a high pressure sensitive environment and has a certain part which is formed of a conductive member, an introduction unit for introducing an etching gas into the process chamber, an eventuation unit for eventuating the process chamber, an electrode unit which is formed of a first electrode exposed in the process chamber and having a mounting surface on which a substrate which will be etched is mounted, and a second electrode exposed in the process chamber and being opposite to the mounting surface of the first electrode and having conductivity, a power supply unit for applying a RF voltage to both electrodes for generating an electric field between the first electrode and second electrode, and an electric field generation unit which includes at least one coil block provided in a back surface of the conductive member and surrounding the process chamber for forming an electric field which is sequentially rotatable in the process chamber and which generates a magnetic field between the first and second electrode for thereby being orthogonal to the electric field based on a variable voltage and current.

### BACKGROUND OF THE INVENTION

1. Field of the Invention

The present invention relates to plasma etching apparatus used for a semiconductor fabrication process, etc., and in particular to a magnetron plasma etching apparatus which is capable of implementing a uniform surface of a wafer using a magnetic coil block for thereby preventing a drifting of plasma ion.

2. Description of the Background Art

In a conventional art, as a magnetron plasma etching apparatus, there are known a dry etching apparatus of a magnetically enhanced reactive ion etching reactor(MERIE) type, a thin film formation apparatus, etc. In the plasma etching apparatus, plasma is formed in a process chamber, and a desired etching or thin film formation is implemented using an operation of an ion, radical, electron, etc. in plasma.

However, in the case of an etching operation which is implemented based on a conventional MERIE, a certain crack occurs in an etched surface of a wafer due to the following problems.

First, a magnetic field formed by four permanent magnets is nearly horizontal with respect to a surface of a wafer in a center portion of a wafer which will be processed in a process chamber of a MERIE apparatus, and a component orthogonal with respect to an electric field is large. Since a magnetic field is not horizontal to a surface of a wafer in an edge portion, a component orthogonal to an electric field is small, and a cycloid movement of an electron does not occur easily.

Second, as an electron moves in a direction vertically orthogonal to a magnetic field by a cycloid movement, an electron density is largely increased in an edge portion of a wafer. Therefore, an ion electrification region is formed between an upper electrode and an opposite electrode of a lower portion due to a high electron density. At this time, a part of the ion region may damage each device of a wafer. In other words, in the case that an electron density is high in plasma, the number of ions injected into each device of the wafer is increased, and a device damage may be further increased. Furthermore, since a magnetic field is rotated in a magnetron etching apparatus, all areas of edge portion of the wafer may be damaged.

Namely, in the construction of the MERIE apparatus, since a magnetic field is applied to a wafer in parallel, plasma density is largely biased by a drifted electric charge particle, so that an electric charge particle is moved. Therefore, an electrified region is formed in both ends of the wafer, namely, is divided into a positive and negative portion. The thusly formed electrified region may destroy or degrade each device in a wafer and damage each device in the wafer.

According to the technology of Japan Tokyo Electron Inc., in order to prevent a damage of each device in the wafer, 32 magnets are rotated, and the density of the plasma is made uniform. However, in the above method, an ion drifting problem may occur by a Lorentz theory in a state that a magnet having a fixed size is in an instant stop state. Therefore, the electric charge particles are moved in the drifting direction, and the density of the plasma is made non-uniform, and the non-uniform density makes the electric charge distribution non-uniform with respect to the surface of the wafer.

According to the USA LAM Corp., plasma confinement ring is used instead of using a magnetic material or magnet as another means. However, in this method, it is impossible to provide a desired uniform density of plasma.

### SUMMARY OF THE INVENTION

Accordingly, it is an object of the present invention to provide a magnetron plasma etching apparatus which is capable of implementing a uniform surface of a wafer in such a manner that a magnetic field is formed in a direction crossing with respect to an electric field using a magnetic coil block, and a gradient space in which a magnetic flux density is weakened in the magnetic field for thereby radiating an electric charge in plasma in a drifting direction.

To achieve the above objects, in a magnetron plasma etching apparatus, there is provided a magnetron plasma etching apparatus which includes a process chamber which may be set to a high pressure sensitive environment and has a certain part which is formed of a conductive member, an introduction unit for introducing an etching gas into the process chamber, an eventuation unit for eventuating the process chamber, an electrode unit which is formed of a first electrode exposed in the process chamber and having a mounting surface on which a substrate which will be etched is mounted, and a second electrode exposed in the process chamber and being opposite to the mounting surface of the first electrode and having conductivity, a power supply unit for applying a RF voltage to both electrodes for generating an electric field between the first electrode and second electrode, and an electric field generation unit which includes at least one coil block provided in a back surface of the conductive member and surrounding the process chamber for forming an electric field which is sequentially rotatable in the process chamber and which generates a magnetic field between the first and second electrode for thereby being orthogonal to the electric field based on a variable voltage and current.

### BRIEF DESCRIPTION OF THE DRAWINGS

The present invention will become better understood with reference to the accompanying drawings which are given only by way of illustration and thus are not limitative of the present invention, wherein;

FIG. 1 is a cross sectional view illustrating a magnetron plasma etching apparatus according to the present invention;

FIG. 2 is a plane view illustrating an etching apparatus which shows a high electron density region of an apparatus according to the present invention;

FIGS. 3A and 3B are enlarged cross sectional views with respect to primary and secondary magnetic coil blocks in an etching apparatus of FIG. 2 according to the present invention; and

FIG. 4 is a graph of a relationship with an etching rate in the case that a magnetic coil block is used in the constructions of FIGS. 3A and 3B.

### DETAILED DESCRIPTION OF THE PREFERRED EMBODIMENTS

The magnetron plasma etching apparatus according to a preferred embodiment of the present invention will be described.

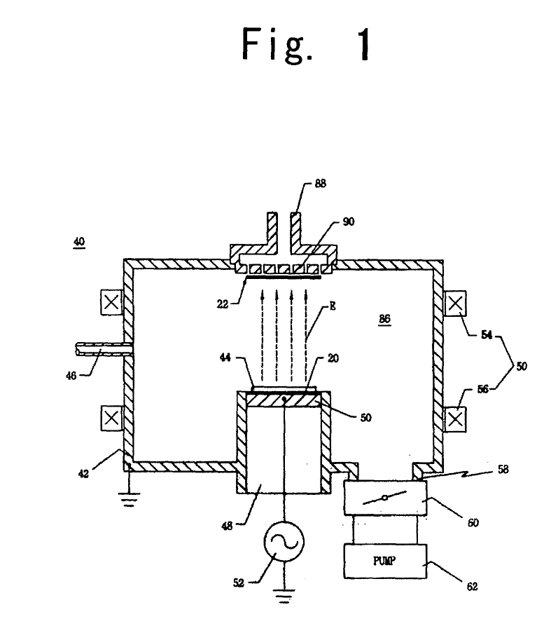

FIG. 1 is a cross sectional view illustrating a magnetron plasma etching apparatus according to a first embodiment of the present invention.

As shown therein, the MERIE apparatus 40 includes a process chamber 42 in a vacuum state as an etching chamber in a processing region, a processed member 44 such as a semiconductor wafer, etc. in the process chamber 42, an opening 46 into which the processed member 44 is inserted, and a mounting stand 48 having a chuck 50 for clamping the processed member 44 in the process chamber 42 and chucking the same by a static electricity manner. In addition, the MERIE apparatus 40 is installed opposite to the mounting stand 48 and has a distribution plate 88 which has a plurality of apertures.

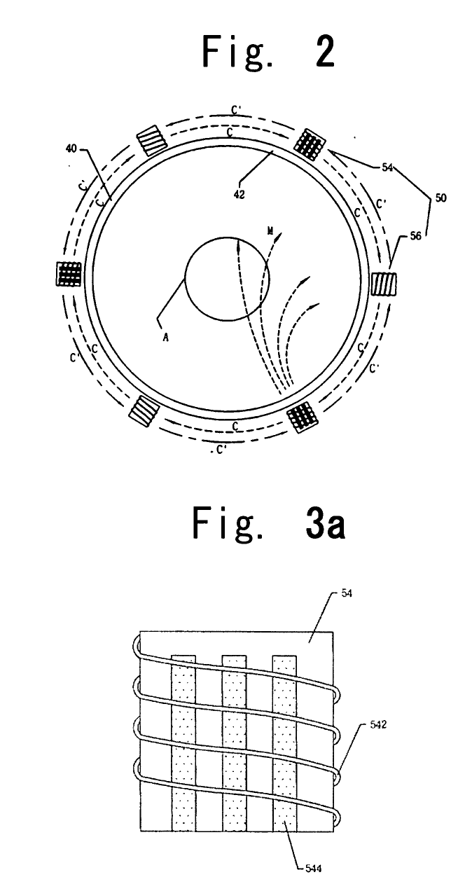

As shown in FIG. 1, the process chamber 86 may be made vacuum, and an etching gas may be inputted thereinto through the distribution plate 88 of an introduction pipe. In the interior of the process chamber 86, there are provided a flat plate shaped cathode electrode 20 in which a wafer A is mounted as a processed member, and a flat plate shaped n anode electrode 22. The cathode electrode 20 and the anode electrode 24 are formed of a conductive material. For example, the anode electrode 24 is connected to the ground. In addition, a RF power 52 outputs a high frequency power(for example, 13.56 MHz or 27.12 MHz) to the mounting stand 48 for thereby generating plasma. In addition, the cathode electrode 24 is adapted to control a DC bias. Therefore, an electric field E is horizontally generated in an arrow direction indicated by the dot line based on a cathode coupling method between the parallel flat plate electrodes of the cathode electrode 20 of the upper side and the anode electrode 24 of the mounting stand 48. A magnetic field or a gradient M of the magnetic field is applied from the magnet apparatus 54 in the direction of the arrow direction indicated by the dotter line as shown in FIG. 2.

In addition, the MERIE apparatus 40 includes a high frequency RF power 52, a gas discharging pipe 58 for discharging an etching gas, a vacuum pump 62 for pumping through a throttle valve 60, and a magnetic coil block 50 which includes a first and second magnetic coil block 54, 56 controlled by a current or power and installed in a pair and surrounding the process chamber 86 and forming a magnetic field in the process chamber 86 as a magnetic field applying means.

FIG. 2 is a cross sectional view illustrating a magnetron plasma etching apparatus according to a first embodiment of the present invention.

As shown therein, there are shown a plane in which a magnetic coil block 50 is formed for forming a gradient M of the magnetic field, and a distribution of the gradient M indicated by a curve arrow of the magnetic field. In this embodiment, the magnetic coil block 50 is formed of a primary side structure and a secondary side structure. In detail, five magnetic coil blocks 54 which is a primary structure are installed in the outer direction of the wafer A, and the secondary coil block 56 which is a secondary structure in the lower side are provided in pair with the primary magnetic coil block 54. The gradient M of the magnetic field applied to the coil block 50 is formed in such a manner that the size of the primary magnetic coil block 54 is larger than that of the secondary magnetic coil block 56, so that a magnetic field is biased in the direction of the secondary magnetic coil block 56.

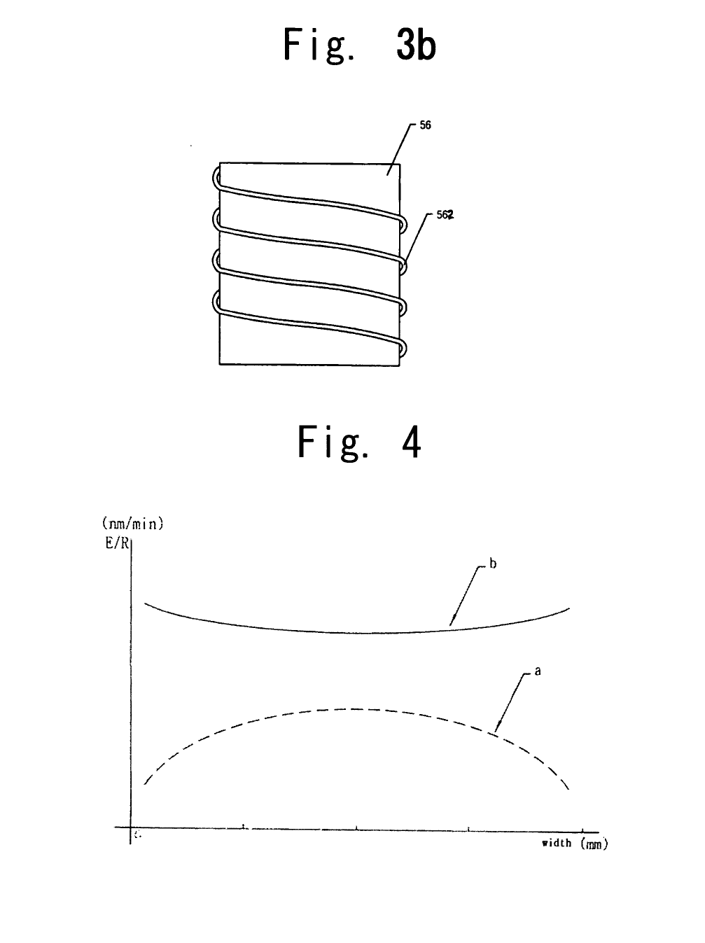

FIGS. 3A and 3B are enlarged cross sectional views of the primary and secondary magnetic coil blocks in the etching apparatus of FIG. 2 according to the present invention. In the structure of the primary coil block 54, the gradient M of the magnetic field is formed using the magnetic coil 542 and the ferrite 544. The secondary coil block 56 includes at least one coil. The primary and secondary magnetic coil blocks 54, 56 are slowly rotated for increasing the density of the plasma(at a speed of higher than 10 msec). At this time, the AC power or DC power is applied for generating an AC or DC magnetic field.

Here, in the case that the AC power is applied to the primary and secondary magnetic coil blocks 54, 56, the AC power having a frequency from 1 Hz to a few hundreds of Hz is applied to the primary and secondary magnetic coil blocks 54, 56. Here, the primary and secondary magnetic coil blocks 54, 56 are rotated in the direction indicated by the arrow C or C′ about the processor chamber 86 near the etching apparatus of FIG. 2. Here, the arrow C shows a forward direction indicated by the dotted line, and the arrow C′ shows the direction reverse to the direction of the arrow C. In addition, the AC power applied to the magnetic coil blocks 54, 56 includes a frequency of 1 Hz to 100 Hz.

Selectively, in the case that the power is applied to the primary and secondary magnetic coil blocks 54, 56, it is possible to apply the DC power which is controllable by a control apparatus(not shown).

As the DC power is applied, the DC magnetic field is generated using the coil and ferrite 542, 544 for increasing the plasma density in the process chamber 86, namely, for increasing the collision frequency of an electric charge particle in the primary magnetic coil block 54. In addition, in order to increase the plasma density, the secondary magnetic coil block 56 generates a desired DC magnetic field using the secondary magnetic coil 562.

In addition, in the coil block 50, it is possible to apply a DC power or AC power at the same time using two or three coil blocks which are additionally provided from the outside or based on a combination of the same. In detail, it is possible to sequentially apply the power to the first, second, third, fourth and fifth coil blocks, and the power may be concurrently applied to the first and second coil blocks. In addition, the power may be concurrently applied to the third and fourth coil blocks. In another embodiment, the power may be concurrently applied to the first, second and third coil blocks. The power may be concurrently applied to the second, third and fourth coil blocks. In this case, the primary magnetic coil block 54 may be fixed. Therefore, it is possible to obtain a uniform plasma distribution by rotating in the same direction or in the reverse direction.

The magnet of the secondary coil block 56 is increased, so that it is possible to implement a uniform gradient M of the magnetic field without drifting in one direction. As shown in FIG. 4, it is possible to increase the density by more than 1.5˜2 times compared to a theoretical density value of the plasma, for thereby enhancing an etching rate.

In the primary side structure, the coil block 50 is formed of at least one coil 542 and the ferrite 544 in the primary side magnetic coil block 54. The primary magnetic coil block 54 is formed of at least five coils and ferrites 542, 544. The AC power or DC power is applied to the above coil block. The field B is varied to a degree of about 0˜250 Gauss based on the voltage and current for thereby controlling the plasma distribution in the chamber 86. Preferably, the primary structure is directed to a coil block having at least five coils 562 and the ferrite 564. The AC or DC power is applied to the above coil block. The field B is varied to a degree of about 0˜250 Gauss based on the voltage and current for thereby controlling the plasma degree.

In addition, in the secondary structure, the secondary magnetic coil block 56 includes at least one magnetic coil block 562. Here, only at least one coil is provided without providing the ferrite compared to the primary coil structure. The AC or DC power is applied to the above secondary coil block, and the field B is varied to a degree of 0˜200 Gauss for thereby controlling the same.

Here, in the primary coil, the magnetic coil and the ferrites 562, 564 are concurrently used, and the gradient M is controlled, so that it is possible to concurrently transfer in the chamber 86. The secondary coil 562 confines the drifting of the plasma ion, so that the ions formed in the chamber 86 prevents the ions formed in the chamber 86 from being pumped out or drifted for thereby increasing an etching rate(E/R nm/min) of the wafer edge portion. In other words, it is possible to compensate the damage of the wafer device based on a strong magnetic field formed in the primary coil block.

As shown in FIGS. 1 and 2, the anode electrode 22 is opposite to the cathode electrode 20. The magnetic block coil 54, 56 is provided in a portion vertical with respect to both electrodes 20, 22. Therefore, an electric field E of a horizontal component is formed in the neighboring portion of the wafer A. In addition, a rotation magnetic field is formed between the chamber portion 30 based on the rotation of the magnetic coil block 54, 56. The size of the primary magnetic coil block 54 is larger than that of the secondary magnetic coil block 56 because the magnetic field formed based on the magnetic coil block 54, 56 flows from the higher magnetic field of the primary side to the lower magnetic field of the secondary side.

In addition, as shown in FIG. 2, the magnetic field M of a horizontal component and gradient component indicated by the dotted line is formed in the peripheral portion of the wafer A. The magnetic field E is formed for the reason that the cycloid movement of electrons is implemented in the direction orthogonal to each other based on the left had rule of Fleming by an operation between the electric field formed between the upper chamber portions 30 and the magnetic component orthogonal to the electric field, so that a collision frequency between the electrons and gas molecules is increased.

The gradient of the magnetic field formed by the magnet 54 is nearly horizontal in the upper side of the center of the wafer A as indicated by the dotted line of FIG. 2 and has a certain circular inclination increasing in the direction of the peripheral portion(namely, the vertical component is increased). In a complementary electric field formed by both electrodes, the anode electrode includes an electrode portion which is vertical with respect to the electrode portion parallel with respect to the cathode electrode. Therefore, there is only vertical component in the center portion of the wafer A, however the horizontal component is increased in the peripheral portion of the wafer A.

Therefore, the cycloid movement of the electrons which is caused by the electric field E vertically crossing with respect to the gradient M of the magnetic field is uniform in the center portion and peripheral portion of the wafer A. In the apparatus according to a preferred embodiment of the present invention, the generation amount of the plasma is uniform in the center portion and neighboring portion of the wafer A, so that it is possible to implement a uniform surface process of the wafer.

FIG. 4 is a graph of a measured result. As shown therein, the horizontal axis is a distance “d”(unit is mm) from the center of the wafer 100, and the vertical axis is an etching rate E/R(unit is rn/mm).

As shown in FIG. 4, in the variation of the etching rate, the etching rate component(“b” indicated by the solid line) is more uniform in the case that the first and second magnet coil blocks 54, 56 are used, compared to the conventional etching rate component(“a” indicated by the dotted line). Here, in the uniform etching rate “b”, since the plasma density is increased by more than 2 times based on the magnet coil and ferrite effect, so that the etching rate “b” is delayed in the center portion of the wafer A, and is increased in the peripheral edge portion. What the size of the ions is significantly decreased in an outer wall of the chamber 86 means that the second coil block compensates. Therefore, it is possible to significantly decrease the unbalance of the etching rate that the ion is increased based on the plasma confinement by the secondary coil.

As described above, a process gas is plasma-processed by the magnetron discharge by a high frequency electric field and a magnetic field. When etching the wafer A, a certain gradient by which a magnetic flux density of the drifting direction D is weakened based on the Lorentz force is provided with respect to the magnetic field of the coil block which is applied in the direction crossing with respect to a high frequency wave electric field. Therefore, since the plasma density is uniform, it is possible to implement a uniform etching without decreasing the etching rate.

In addition, in the above description, the construction that the present invention is adapted to the plasma etching was described in detail. However, the present invention may be well adapted to all cases that a magnetron plasma is generated. For example, the present invention may be adapted to a sputtering apparatus, plasma CVD apparatus, an ion resource, an electron beam source, etc.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. In a magnetron plasma etching apparatus, a magnetron plasma etching apparatus, comprising:
a process chamber which may be set to a high pressure sensitive environment, and at least one portion of the process chamber is formed of a conductive member;
an introduction means for introducing an etching gas into the process chamber;
an eventuation means for eventuating the process chamber;
an electrode means which is formed of a first electrode exposed in the process chamber and having a mounting surface on which a substrate which will be etched is mounted, and a second electrode exposed in the process chamber and being opposite to the mounting surface of the first electrode and having conductivity;
a power supply means for applying a RF voltage to both electrodes for generating an electric field between the first electrode and second electrode; and
a magnetic field generation means which is installed to surround the process chamber and forms a magnetic field which is sequentially rotatable in the process chamber, said magnetic field being orthogonal with respect to the electric field based on a variable voltage and current between the first and second electrodes.

2. The apparatus of claim 1, wherein said magnetic field generation means includes at least one coil block which is installed in a back surface of the conductive member.

3. The apparatus of either claim 1 or claim 2, wherein said coil block includes:
a primary coil block formed of a plurality of coils and a plurality of ferrites; and
a secondary coil block formed of a plurality of coils.

4. The apparatus of either claim 1 or claim 2, wherein an AC or DC power is applied to the primary and secondary magnetic coil blocks so that the primary and secondary magnetic coil blocks are rotated in the reverse direction each other at a speed faster than 10 msec for thereby generating AC or DC magnetic field.

5. The apparatus of claim 4, wherein in the case that the AC power is applied to the primary and secondary magnetic coil blocks, an AC power having a frequency from 1 Hz to 100 Hz is applied to the primary and secondary magnetic coils, respectively.

6. The apparatus of either claim 1 or claim 5, wherein in the case that the DC power is applied to the primary and secondary magnetic coil blocks, a DC power is applied thereto for thereby controlling using the control apparatus.

7. The apparatus of either claim 1 or claim 2, wherein in said coil block, at least two other coil blocks are combined externally, and a DC power is applied thereto at the same time, respectively.

8. The apparatus of claim 7, wherein in the case that the coil block applies a DC power to the primary, secondary, and third coil block at the same time, respectively, the primary and secondary magnetic coil blocks are rotated in the same direction at the same time.

9. The apparatus of claim 7, wherein in a rotational magnetic field of the primary and secondary magnetic coil blocks, the size of the magnetic field of the primary magnetic coil block is larger than the size of the magnetic field of the secondary magnetic coil block.

10. The apparatus of either claim 1 or claim 2, wherein said primary coil block is adapted to applying a magnetic field of a range of 0 Gauss to 250 Gauss of a substrate.

11. The apparatus of either claim 1 or claim 2, wherein said secondary coil block is formed of a coil capable of applying a magnetic field of a range from 0 Gauss to 200 Gauss of a substrate which confines an ion drifting of plasma, for thereby confining an ion drifting of plasma.
